(19) United States
(12) Patent Application Publication
(10) Pub. No.: US 2006/0151845 A1
(43) Pub. Date: Jul. 13, 2006

(54) Method to control interfacial properties for capacitors using a metal flash layer

(76) Inventor: Shrinivas Govindarajan, Niskayuna, NY (US)

Correspondence Address: SLATER & MATSIL LLP, 17950 PRESTON ROAD, SUITE 1000, DALLAS, TX, 75252, US

(21) Appl. No.: 11/031,596

(22) Filed: Jan. 7, 2005

(51) Int. Cl. H01L 29/76

(52) U.S. Cl. 257/411

(57) ABSTRACT

A capacitor can be formed by depositing a metal flash layer (e.g., Ti) over a substrate (e.g., silicon). A dielectric layer (e.g., a high K dielectric) is formed over the metal flash layer. A conductive layer is formed over the dielectric layer such that the conductive layer is capacitively coupled to the substrate and/or the metal flash layer. The device can be annealed such that the metal flash layer changes state and such that a capacitance between the conductive layer and the substrate and/or the metal flash layer is increased.

### REFERENCE TO RELATED APPLICATIONS

This application is related to the following co-pending applications, both of which are incorporated herein by reference: application Ser. No. ______, filed ______, and entitled “High Dielectric Constant Materials” (Attorney Docket 2004P54456) and application Ser. No. ______, filed ______, and entitled “DRAM with High K Dielectric Storage Capacitor and Method of Making the Same” (Attorney Docket 2004P54457).

### TECHNICAL FIELD

The present invention relates generally to semiconductor devices and methods, and more particularly to a method to control interfacial properties for capacitors using a metal flash layer.

### BACKGROUND

Capacitors are elements used extensively in semiconductor devices for storing an electric charge. Capacitors essentially comprise two conductive plates separated by an insulator. The capacitance, or amount of charge held by the capacitor per applied voltage, is measured in farads and depends upon the area of the plates, the distance between them, and the dielectric value of the insulator, as examples. Capacitors are used in filters, in analog-to-digital converters, memory devices, and control applications, and many other types of semiconductor devices. For example, a dynamic random access memory (DRAM) cell includes a storage capacitor coupled in series with an access transistor. Data can be stored into and read out of the storage capacitor by passing charge through the access transistor and into the capacitor.

For DRAM capacitors, some key requirements for sub-70 nm technologies are low leakage current, low Equivalent Oxide Thickness (EOT), minimization of polysilicon depletion, adequate band offsets (for the dielectric), and thermal stability during subsequent processing. To achieve these requirements, the idea of using MIS (metal-insulator-silicon) or MIM (metal-insulator-metal) capacitors is known. A key challenge is to optimize the various interface properties and to use dielectrics with high capacitance. For applications involving gate electrodes, additional requirements include minimization of tunneling leakage current and gate resistance.

### SUMMARY OF THE INVENTION

In one aspect, the present invention provides a technique to control the interface between silicon (which is prone to forming a native oxide) and the metal electrode or dielectric, e.g., in order to achieve EOT less than 1 nm. Use of a pure metal layer in the vicinity of the interface will help to minimize the interfacial layer contribution to EOT. Combining this with a suitable dielectric layer with high dielectric constant will help minimize EOT. Embodiments of this invention propose the use of a pure metal flash layer (e.g., Ti, Ta, Ru, V, Nb, Sr, Pr, Dy, La, Gd) to minimize the adverse contribution of the interfacial layer.

In accordance with a preferred embodiment of the present invention, a capacitor can be formed by depositing a metal flash layer (e.g., Ti) over a substrate (e.g., silicon). A dielectric layer (e.g., a high K dielectric) is formed over the metal flash layer. A conductive layer is formed over the dielectric layer such that the conductive layer is capacitively coupled to the substrate and/or the metal flash layer (or a metallic compound formed at the interface). The device can be annealed such that the metal flash layer changes state and such that the capacitance between the conductive layer and the substrate and/or the metal flash layer is increased.

In accordance with another preferred embodiment of the present invention, a capacitor is formed by forming a metal layer in physical contact with a silicon body. The metal layer is formed from a material having a high affinity for oxygen and a melting point above about 1000° C. (a lower temperature (e.g., 500 to 700° C.) may be tolerable depending the subsequent processing steps). A layer of high K dielectric material is formed in physical contact with the metal layer. The high K dielectric material has a dielectric constant greater than about 10 (or in some embodiments greater than 20). A conductive layer is then formed over the high K dielectric material layer. An interface between the high K dielectric layer and the metal layer/silicon body can be modified by performing an annealing step.

In yet another embodiment, a sacrificial gettering layer is formed over a substrate. A dielectric layer is also formed over the substrate. An interface that lies between the dielectric layer and the substrate is modified in a process step where the sacrificial gettering layer is partially or completely converted to a new phase during the modifying step. The gettering layer may be between the substrate and the dielectric or over the dielectric, or within the dielectric.

In accordance with another preferred embodiment of the present invention, a capacitor is formed by forming a metal layer in physical contact with a silicon body. The metal layer is formed from a material having a high affinity for oxygen and a melting point above about 1000° C. (a lower temperature, for example, about 500 to 700° C., may be tolerable depending the subsequent processing steps). A nitride of the metal is formed above the metal layer—either as a single layer or as compositionally-graded layer. This layer would serve as a diffusion barrier for Si or O atom diffusion. A thicker metal electrode is an optional layer which can be used for developing the bottom electrode for an MIM capacitor. A layer of high K dielectric material is formed in physical contact with the metal layer. The high K dielectric material has a dielectric constant greater than about 10 (or in some embodiments greater than 20). A conductive layer is then formed over the high K dielectric material layer. An interface between the high K dielectric layer and the metal layer/silicon body can be modified by performing an annealing step.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a simplified view of a capacitor structure of the present invention;

FIG. 2 is a flow chart of a preferred embodiment;

FIG. 3 illustrates a simplified view of a capacitor structure of an alternate embodiment; and

FIG. 4 is a cross-sectional view of a transistor that utilizes concepts of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a capacitor structure. Embodiments of the invention can also be applied, however, to other integrated circuit structures that include a conductor adjacent to a dielectric. Two specific examples, namely a capacitor and a transistor gate, are provided. Concepts of the invention can also be applied to other structures.

In one aspect, the present invention provides an enhanced interface between a conductor and an insulator. To address the interface issue, embodiments of the invention implement the strategic use of pure metals to engineer the oxygen (or nitrogen) potential at the interfaces. For example, one embodiment is based on the fact that some pure metals have a very strong tendency to form solid solutions with oxygen (or nitrogen), prior to conversion into oxides (or nitrides). The reduction of an Si—O based oxide to Si and transfer of oxygen to the metal flash layer will help to increase the overall capacitance and reduce leakage current (for a specific thickness).

Depending on the post-deposition annealing conditions, the state of the starting surface (e.g., HF-last, nitride, oxide or native oxide), thickness and location of this flash layer, a silicide (e.g., TiSi₂), an oxide (e.g., TiO₂) or a silicate (e.g., TiSiOₓ) can be formed (either as stoichiometric compounds or sub-stoichiometric solid solutions). Each of these situations provides some benefits (e.g., by eliminating and/or transforming the lower k interfacial layer). For example, formation of a metal silicide at the interface would help create a metal electrode since metal silicides are conductive. For example, the appropriate phase of TiSi₂ (e.g. C54) or TaSi₂ results in a bulk resistivity less than 40 μΩ.cm. The uniformity of this layer can be controlled through the deposition and post-deposition treatments.

Another option is to follow the metal deposition with the formation of a nitrogen containing metallic layer, for example TiN. Other examples of possible nitride based materials that can be used in this context include TaN, RuN, TaSiN, TiSiN, VN, NbN, HfN and combinations of these. This offers the potential to form a metallic nitride, which could also serve as a diffusion barrier layer. Possible deposition schemes include either direct contact of the metal with the silicon substrate or incorporation of the metal layer after depositing a very thin (e.g., about 1 to 5 nm thick) layer of the dielectric material. In both cases, the metal layer acts like an “oxygen-sponge” and depletes the oxygen content of the interfacial layer.

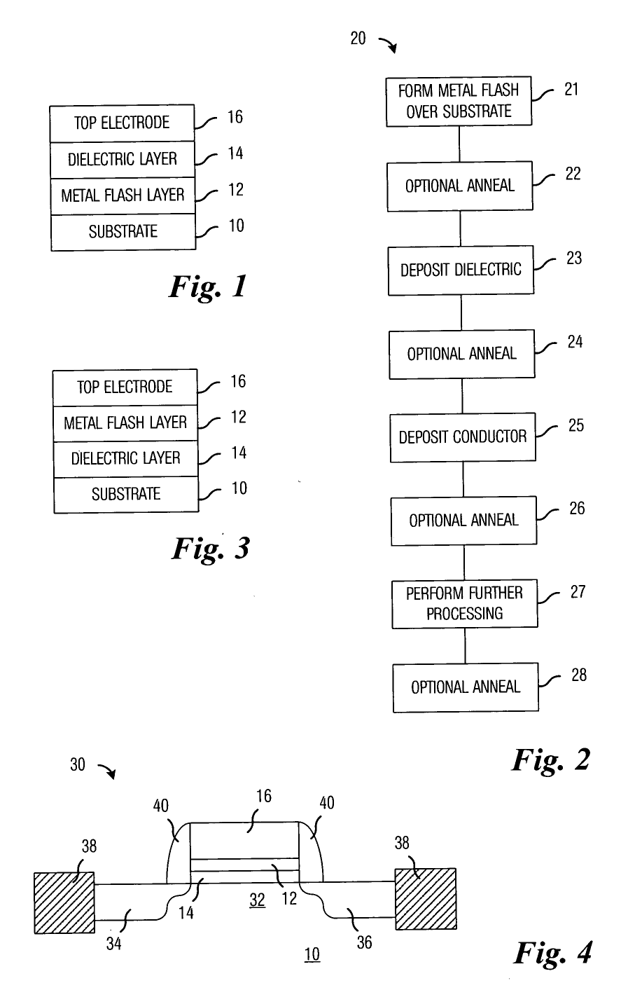

A schematic of one structure that utilizes concepts of the present invention is shown in FIG. 1, which illustrates a capacitor as deposited. In this embodiment, the capacitor (as deposited) starts with the substrate (typically Si), followed by a thin metal (e.g., Ti, Ta, Ru, La, V, Nb, Pr, Dy, Sr, Gd) flash layer, an optional bottom metal electrode layer (e.g., 1 to 5 nm thick, made from Ru, Ti, Ta, Hf, or nitrides/carbonitrides deposited by various possible methods—e.g., Atomic Layer Deposition, Metallorganic CVD, Molecular Beam Epitaxy, or others), a high K dielectric layer (e.g., HfO₂—Ti nanolaminate), followed by a metal electrode (e.g., Ru, Ti, Ta, Hf, or nitrides/carbonitrides).

The silicon substrate 10 can be an upper portion of a bulk silicon substrate or a silicon layer over another layer. As examples, the silicon layer can be part of a silicon-on-insulator (SOI) substrate, an epitaxially grown layer over another layer (e.g., silicon over silicon germanium), or a silicon layer formed by a wafer bonding technique. The silicon layer could also be a layer formed over a substrate, e.g., a polysilicon layer used as a gate electrode or an electrode used in a stacked capacitor. Semiconductors other than silicon, e.g., germanium, silicon germanium, gallium arsenide and others, could alternatively be used. Alternatively, a non-semiconductor substrate 10 can be used. For example, the capacitor structure can be formed on a dielectric layer.

The embodiment depicted in the figure includes a metal layer 12 in direct contact with a silicon substrate 10. In one example, the metal flash layer 12 can preferably be any metal with a high affinity for oxygen and a melting point (both for the solid solution with oxygen and the oxide) above about 1000° C. In various embodiments, the bottom electrode metal could comprise either flash metal (e.g., Ti) only, a flash metal with another metal electrode (e.g., TiN, TaN, Ru, or others), or only the metal electrode.

In a first example, the first metal layer 12 can be titanium formed to a thickness of about 1 to about 10 nm. This layer can be deposited by atomic layer deposition using a thermal process (preferably) or a suitable plasma-enhanced deposition process, e.g., Ti(OEt)₄ or TiCl₄ with a H₂ plasma. The metal layer can be converted to a silicide (or silicate) or oxide layer based on film thickness and annealing conditions (temperature, ramp rate, oxygen or nitrogen partial pressures).

The metal layer 12 can be deposited using appropriate precursors and an atomic layer deposition (ALD) process, as an example. Plasma enhancement would facilitate reduction of the metal ligand after attachment to the substrate. An example of such a deposition process is the use of PEALD (plasma enhanced ALD) to deposit Ti. TiCl₄ is the precursor for Ti and atomic hydrogen (produced with an RF plasma) is used as the reducing agent. A suitable example of a Ti ALD is described in Kim et al., “Growth kinetics and initial stage growth during plasma-enhanced Ti atomic layer deposition,” Journal of Vacuum Science and Technology, A 20(3), May/June 2002, pp. 802-808, which paper is incorporated herein by reference.

In other embodiments, other deposition techniques could be used. For example, for deep trenches, such as those used in trench DRAMs, a thermal ALD process may be used to ensure adequate step coverage. Other options include thermal ALD using TiCl4, Ti-amides, or Ti-alkoxides with H₂O or O₃. For gate electrodes with less aggressive aspect ratios, other methods can be used to deposit Ti, e.g., physical vapor deposition (PVD) from a Ti target, chemical vapor deposition (CVD), or molecular beam epitaxy (MBE).

After an adequate film thickness is deposited, the film can be subjected to a high temperature anneal. An anneal at this point in the process flow is optional. Preferably, the anneal is performed using a rapid thermal process (RTP) with a controlled atmosphere. Alternatively, a controlled furnace anneal could be utilized. In the RTP example, the structure can be heated to a temperature between about 400° C. and about 1100° C. for a time of about 10 to about 60 seconds. In the furnace anneal example, the structure can be heated to a temperature between about 400° C. and about 1000° C. for a time of about 5 to about 30 minutes.

Dielectric 14 is then deposited over the layer 12. A wide variety of dielectrics can be used. For example, dielectric 14 can be an oxide (e.g., silicon dioxide) or a nitride (such as silicon nitride, e.g., Si₃N₄). Combinations of oxides and nitrides can also be used. For example, dielectric 14 can be silicon oxynitride (SiON) or a composite layer such as an oxide-nitride-oxide (ONO) layer. With silicon oxide, silicon nitride, and combinations thereof, the preferred physical thickness of dielectric 14 is between about 1 nm and 10 nm, preferably about 3 nm, depending on the dielectric constant of the layer.

The process of the present invention is especially useful with high K dielectrics, such as those materials with a dielectric constant greater than about 10 in one embodiment and a dielectric constant greater than about 20 in another embodiment. Suitable examples include Hf or Al based oxides such as Al₂O₃, HfO₂, and Hf—Al—Ox. Other examples include titanium oxide (TiO₂), lanthanum oxide (e.g., La₂O₃), barium-strontium titanate (BST) ((BaSr)TiO₃ or BSTO), and strontium titanate (STO).

Co-pending application Ser. No. ______ (Docket No. 2004P54456) describes a number of high K dielectrics that are particularly useful in embodiments of the present invention. For example, that application provides a dielectric layer with K greater than 25 and adequate conduction band offset with silicon. Exemplary embodiments proposed in the co-pending application use the following material systems: HfᵤTiᵥTa_{w}OₓN_{y}, HfᵤTiᵥOₓN_{y}, TiᵤSrᵥOₓN_{y}, TiᵤAlᵥOₓN_{y} and HfᵤSrᵥOₓN_{y} (where u, v, w, x, and y are the atomic proportions of the elements in the dielectric stack).

The dielectric layer 14 can be deposited by ALD of the individual components. The thickness of this layer, thicknesses of the individual sub-layers, and the sequence of the layers is variable and depends on the capacitance enhancement to be achieved. In the preferred embodiment, the dielectric layer 14 has a physical thickness of between about 2 nm to about 20 nm.

An optional anneal can be performed after depositing the dielectric layer 14. This anneal can be either a rapid thermal anneal or a furnace anneal, as examples. In the rapid thermal anneal example, the structure can be heated to a temperature between about 400° C. and about 1100° C. for a time of about 10 to about 60 seconds. In the furnace anneal example, the structure can be heated to a temperature between about 400° C. and about 1000° C. for a time of about 5 to about 30 minutes.

After depositing dielectric layer 14, the top metal 16 can be deposited. The top metal electrode 16 could be either pure metal (e.g., Ru, Hf, Ti, Ta, or others) or nitrides (e.g., TiN, TaN, HfN, combinations of these) or carbo-nitrides (e.g., TiCN, NbCN, HfCN, TaCN, or others). For example, TiN could be deposited by ALD using TiCl₄ and NH₃. Alternative deposition methods include PVD, MOCVD, MBE and others.

This structure can then be subjected to an anneal (e.g.; RTP or furnace-based, with controlled oxygen and nitrogen partial pressures), if required. One alternative approach would be to skip the anneal and cap this structure with polysilicon. Downstream anneals could accomplish the required film stabilization. Some nitrides, e.g., HfN, are extremely prone to oxidation and, therefore, it is desirable that these types of layers be capped with a more stable film (e.g., TiN) prior to atmospheric exposure.

The preferred embodiment of this invention uses an oxygen/nitrogen gettering layer (sacrificial in nature since it may be partially or completely converted to a new phase) as a means of modifying the interface between the dielectric layer and the metal/substrate layer. Metals such as titanium form a solid solution with oxygen and are, therefore, very effective as gettering layers. Furthermore, formation of a silicide layer at the interface would be very useful for MIM capacitors. The segregation of oxygen can be tailored (through temperature, time, and partial pressure control) such that a pure silicide is in contact with the silicon substrate and the silicate/oxide is formed above the silicide layer. This layer can be deposited with PVD using a Ti target for shallow structures, e.g., for gates.

FIG. 2 shows a simplified flow chart 20 of the steps of the present invention. In this process, the metal flash 12 is formed (step 21), followed by deposition of the dielectric 14 (step 23) and deposition of the conductor 16 (step 25). This chart serves to show that the anneal step(s) mentioned earlier can be performed in any of a number of steps in the process flow. For example, the anneal can be performed after metal 12 formation but before dielectric 14 deposition (step 22), after dielectric 14 formation but before deposition of conductor 16 (step 24), immediately after metal 16 formation (step 26), or even after further processing (steps 27, 28).

An alternate embodiment of the invention is illustrated in FIG. 3. In this example, the metal flash 12 is formed over the dielectric layer 14. If the dielectric layer 14 is thin enough, e.g., 2 to 10 nm thick, the interface between the dielectric layer 14 and substrate 10 can be cleaned up by a metal flash in this location. The thickness of the dielectric could be around 1 to 3 nm. An optional anneal step could follow the metal flash layer deposition. The anneal would be between 400° C. to 1100° C. for 10 to 60 seconds and RTP at 400° C. to 1000° C. for 5 to 30 minutes for an anneal. The anneal could be controlled so as to form either a TiOx solid solution or an oxide of Ti (e.g., TiO₂). As with the bottom electrode, the top electrode metal layer 12 could comprise either flash metal (e.g., Ti) only, a flash metal with another metal electrode (e.g. TiN, TaN, Ru, or others), or only the metal electrode.

In other embodiments, the bottom metal electrode 12 and, similarly, the top metal electrode 16 are optional. Also, the embodiment of FIG. 3 can be modified so that a dielectric deposition continues above metal 12. In this case, the flash layer 12 would be encapsulated within the dielectric. If pure TiO₂ is formed during the subsequent anneal, this would help increase the dielectric constant of the stack.

The steps of the present invention can be utilized in a number of applications. An example of DRAM structures that can utilize this invention is described in co-pending application Ser. No. ______ (Attorney Docket 2004P54457), which application is incorporated herein by reference. In another example, MIM (metal-insulator-metal) capacitors utilizing aspects of the present invention can be implemented in mixed signal and analog applications.

FIG. 4 illustrates another example of device, namely a transistor 30 that can utilize aspects of the present invention. In this case, the capacitive structure of FIG. 3 is utilized as a channel/gate structure of a transistor 30. The transistor 30 includes a channel 32 formed in a semiconductor (e.g., silicon) body 10 between source/drain regions 34 and 36. Gate dielectric 14, which can be any of the dielectrics described herein, is formed over the channel layer.

The metal flash layer 12 is formed over the gate dielectric layer 14. This layer 12 can be formed of the materials and by the processes described herein. A gate electrode 16, which can be formed of polysilicon, is formed over the metal layer 12. These materials may be processed as described above. FIG. 4 also shows isolation regions 38 (e.g., shallow trench isolation) and gate sidewall spacers 40, which are known in the art.

To form the transistor device, the isolation regions 38 are formed in the semiconductor body using known techniques. While shallow trench isolation is the preferred technique, other isolation, such as field isolation (e.g., LOCOS), can also be used.

The gate dielectric layer 14 is deposited on the semiconductor substrate. The gate dielectric can be an oxide (e.g., SiO₂), a nitride (e.g., Si₃N₄), or combinations of oxides and nitrides (e.g., SiON or ONO). Alternatively, a high K dielectric as discussed here and in those co-pending applications that are incorporated by reference.

Flash metal layer 12 is then formed over the dielectric 14, using the processes described herein. Formation of the flash metal layer has been described above. The remainder of the gate (if included) can then be deposited. For example, top electrode 16 can be formed from polysilicon. A silicide layer (e.g., titanium silicide, tantalum silicide, cobalt silicide, nickel silicide), which is not shown, can be formed over (or be a part of) electrode 16. If included, the silicide can be formed before or after (e.g., salicide) gate patterning.

The gate layers 12 and 16, and possibly the dielectric layer 14, can then be patterned in the shape of the gate. At this point, lightly doped source and drain regions can be formed by implantation. After forming sidewall spacers using known techniques (e.g., conformal deposition of a dielectric and anisotropic etching), the source and drain regions 34 and 36 can be formed, e.g., by ion implantation. The transistor can be either an n-channel or a p-channel transistor.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of forming a semiconductor device, the method comprising:
providing a substrate;
forming a metal flash layer over the substrate;
forming a dielectric layer over the metal flash layer, the dielectric layer having a thickness between about 1 nm and about 40 nm;
forming a conductive layer over the dielectric layer such that the conductive layer is capacitively coupled to the substrate and/or the metal flash layer; and
annealing the device such that the metal flash layer changes state and such that a capacitance between the conductive layer and the substrate and/or the metal flash layer is increased.

2. The method of claim 1 wherein forming a dielectric layer comprises depositing a material that has a dielectric constant greater than 10.

3. The method of claim 1 wherein forming a metal flash layer comprises forming a layer that includes titanium.

4. The method of claim 3 wherein forming a metal flash layer comprises depositing titanium using an atomic layer deposition (ALD) process.

5. The method of claim 3 wherein annealing the device causes the titanium to form a titanium silicide layer.

6. The method of claim 1 wherein forming a metal flash layer comprises forming a layer comprising a material selected from the group consisting of Ta, Ru, V, Nb, Sr, Pr, Dy, La, and Gd.

7. The method of claim 1 wherein annealing the device occurs after forming the metal flash layer but before forming the dielectric layer.

8. The method of claim 1 wherein annealing the device occurs after forming the dielectric layer but before forming the conductive layer.

9. A method of forming a capacitor, the method comprising:
providing a silicon body;
forming a metal layer in physical contact with the silicon body, the metal layer being formed from a material having a high affinity for oxygen and a melting point above about 1000° C.;
forming a layer of high K dielectric material in physical contact with the metal layer, the high K dielectric material having a dielectric constant greater than about 5;
forming a conductive layer over the high K dielectric material layer; and
modifying an interface between the high K dielectric layer and the metal layer/silicon body by performing an annealing step.

10. The method of claim 9 wherein the metal layer comprises a titanium layer.

11. The method of claim 10 wherein the modifying step comprises forming a material selected from the group consisting of titanium silicide, titanium oxide, and TiSiOₓ.

12. The method of claim 9 wherein the metal layer comprises a material selected from the group consisting of Ta, Ru, V, Nb, Sr, Pr, Dy, La, and Gd.

13. The method of claim 9 wherein the high K dielectric comprises a material selected from the group consisting of HfᵤTiᵥTa_{w}OₓN_{y}, HfᵤTiᵥOₓN_{y}, TiᵤSrᵥOₓN_{y}, TiᵤAlᵥOₓN_{y} and HfᵤSrᵥOₓN_{y}, where u, v, w, x, and y are the atomic proportions of the elements in the dielectric.

14. A method of forming a semiconductor device, the method comprising:
providing a substrate;
forming a sacrificial gettering layer over the substrate;
forming a dielectric layer over the substrate; and
modifying an interface that lies between the dielectric layer and the substrate wherein the sacrificial gettering layer is partially or completely converted to a new phase during the modifying step.

15. The method of claim 14 wherein the gettering layer comprises an oxide gettering layer.

16. The method of claim 15 wherein the gettering layer comprises a titanium layer.

17. The method of claim 16 wherein the titanium layer is converted into a titanium silicide layer during the modifying step.

18. The method of claim 14 wherein forming a sacrificial gettering layer comprises forming a metal flash layer.

19. The method of claim 14 wherein forming a sacrificial gettering layer comprises forming a sacrificial gettering layer in direct physical contact with the substrate.

20. The method of claim 14 wherein forming a sacrificial gettering layer comprises forming a sacrificial gettering layer over the dielectric layer.

21. A transistor device comprising:
a semiconductor body;
a source region disposed in the semiconductor body;
a drain region disposed in the semiconductor body;
a channel region disposed in the semiconductor body between the source region and the drain region;
a dielectric layer over the channel region;
a metal layer overlying and in physical contact with the dielectric layer; and
a conductive gate electrode material overlying the metal layer.

22. The device of claim 21 wherein the conductive gate electrode material includes silicon and wherein the metal layer comprises titanium.

23. The device of claim 22 wherein the metal layer comprises titanium nitride.

24. The device of claim 22 wherein the metal layer comprises titanium silicide.

25. The device of claim 21 wherein the dielectric layer has a dielectric constant greater than about 10.
